(19) United States
(12) Patent Application Publication
(10) Pub. No.: US 2009/0194409 A1
(43) Pub. Date: Aug. 6, 2009

(54) MAGNETRON SPUTTERING MAGNET ASSEMBLY, MAGNETRON SPUTTERING DEVICE, AND MAGNETRON SPUTTERING METHOD

(75) Inventors: Nobuaki Utsunomiya, Kanagawa-ken (JP); Akihiko Ito, Kanagawa-ken (JP)

Correspondence Address: PEARNE & GORDON LLP, 1801 EAST 9TH STREET, SUITE 1200, CLEVELAND, OH, 44114-3108, US

(73) Assignee: SHIBAURA MECHATRONICS CORPORATION, Kanagawa-ken (JP)

(21) Appl. No.: 12/303,441

(22) PCT Filed: Jun. 6, 2007
(86) PCT No.: PCT/JP2007/061454

§ 371 Date: Mar. 6, 2009

(30) Foreign Application Priority Data
Jun. 8, 2006 (JP) 2006-159565

(51) Int. Cl. C23C 14/35

(52) U.S. Cl. 204/192.12; 204/298.16

(57) ABSTRACT

A magnetron sputtering magnet assembly of the invention is a magnetron sputtering magnet assembly movable in a direction generally parallel to a sputtered surface of a target while facing the target, the magnetron sputtering magnet assembly comprises an inner magnet extending in a direction generally perpendicular to the direction of the movement, the N pole or S pole of the inner magnet being opposed to the target; an outer magnet surrounding the inner magnet with a spacing from the inner magnet, the magnetic pole of the outer magnet opposed to the target being opposite to that of the inner magnet; and a nonmagnetic member provided between the inner magnet and the outer magnet and holding the inner magnet and the outer magnet. The magnetic pole opposed to the target in each of the inner magnet and the outer magnet is invertible. The nonuniformity of electron density at the end of the target can be reduced, and the plasma density therein can be made uniform. Thus, the sputtering rate at the target end can be made uniform, and the nonuniformity of film formation distribution on the object under film formation can be reduced. Furthermore, the nonuniformity of target erosion can also be decreased to improve target utilization efficiency.

### Technical Field

This invention relates to a magnetron sputtering magnet assembly, a magnetron sputtering device, and a magnetron sputtering method.

### BACKGROUND ART

There is a magnetron sputtering device for performing sputtering film formation, particularly on a large substrate, which performs sputtering film formation while reciprocating a magnet in the longitudinal direction of the substrate (e.g., Patent Document 1).

The magnetic field generated by the magnet produces a tunnel of the magnetic field on the target surface in a racetrack configuration, and electrons in the discharge space revolve in the magnetic field tunnel. Here, electrons traveling near the corner portion from the long side portion to the short side portion are likely to fly out of the orbit, and the electron density tends to decrease near that corner portion. That is, nonuniformity of electron density occurs in a direction generally perpendicular to the moving direction of the magnet, and causes nonuniformity in the thickness distribution of films formed on the substrate and the distribution of target erosion.

In the portion traversed by the magnet moving in the longitudinal direction of the target, after it is traversed by the front half of the racetrack along the moving direction of the magnet, it is traversed by the other half of the track in which electrons are moving opposite to those in the front-side track, hence canceling out the nonuniformity in the density of electrons. However, at the utmost end of the target (which is not traversed by the magnet, but faces only half of the racetrack), the moving direction of electrons is always the same and cannot cancel out the nonuniformity of electron density.

In Patent Document 1, as shown in FIG. 9, the magnet moves from the longitudinal end position A of the target 150 to the position C so as to draw an arc by moving leftward and simultaneously also moving upward in the figure. After that, the magnet reaches the other end position E only by horizontal (leftward) motion. Then, after the magnet moves downward from the position E to the position F, it moves from the position F to the position H so as to draw an arc by moving rightward and simultaneously also moving downward in the figure. After that, the magnet returns to the original end position by horizontal (rightward) movement and upward movement. Thus, according to Patent Document 1, near the reciprocation end, the magnet is moved also in the width direction (narrow-side direction) of the target 150 in conjunction with its reciprocation so that the moving trajectory of the magnet is varied between the forward path and the return path.

However, even if the magnet is moved in the way as in Patent Document 1, the moving direction of electrons at the utmost end of the target 150 cannot be varied.

### Patent Document 1: JP-A-8-269712

### Disclosure of Invention

### Problems to be Solved by the Invention

This invention provides a magnetron sputtering magnet assembly, a magnetron sputtering device, and a magnetron sputtering method configured to reduce the nonuniformity of electron density at the end of the target.

### Solution to the Problems

According to an aspect of the invention, there is provided a magnetron sputtering magnet assembly movable in a direction generally parallel to a sputtered surface of a target while facing the target, the magnetron sputtering magnet assembly including: an inner magnet extending in a direction generally perpendicular to the direction of the movement, the N pole or S pole of the inner magnet being opposed to the target; an outer magnet surrounding the inner magnet with a spacing from the inner magnet, the magnetic pole of the outer magnet opposed to the target being opposite to that of the inner magnet; and a nonmagnetic member provided between the inner magnet and the outer magnet and holding the inner magnet and the outer magnet, the magnetic pole opposed to the target in each of the inner magnet and the outer magnet being invertible.

According to still another aspect of the invention, there is provided a magnetron sputtering magnet assembly movable in a direction generally parallel to a sputtered surface of a target while facing the target, the magnetron sputtering magnet assembly including: an inner magnetic member extending in a direction generally perpendicular to the direction of the movement; a coil wound around the inner magnetic member; an outer magnetic member surrounding the coil; and a yoke provided on a surface of the inner magnetic member, the outer magnetic member, and the coil, the surface being opposite to a surface thereof opposed to the target, the magnetic pole occurring at an end portion of the inner magnetic member opposed to the target being switched by varying the direction of a current passed through the coil.

According to still another aspect of the invention, there is provided a magnetron sputtering magnet assembly movable in a direction generally parallel to a sputtered surface of a target while facing the target, the magnetron sputtering magnet assembly including: an inner magnet extending in a direction generally perpendicular to the direction of the movement, the N pole or S pole of the inner magnet being opposed to the target; a yoke surrounding the inner magnet with a spacing from the inner magnet; and a nonmagnetic member provided between the inner magnet and the yoke and holding the inner magnet and the yoke, the magnetic pole of the inner magnet opposed to the target being invertible.

According to still another aspect of the invention, there is provided a magnetron sputtering magnet assembly movable in a direction generally parallel to a sputtered surface of a target while facing the target, the magnetron sputtering magnet assembly including: a yoke extending in a direction generally perpendicular to the direction of the movement; an outer magnet surrounding the yoke with a spacing from the yoke, the N pole or S pole of the outer magnet being opposed to the target; and a nonmagnetic member provided between the yoke and the outer magnet and holding the yoke and the outer magnet, the magnetic pole of the outer magnet opposed to the target being invertible.

According to still another aspect of the invention, there is provided a magnetron sputtering magnet assembly movable in a direction generally parallel to a sputtered surface of a target while facing the target, the magnetron sputtering magnet assembly including: an inner magnet extending in a direction generally perpendicular to the direction of the movement, the N pole or S pole of the inner magnet being opposed to the target, and the magnetic pole of the inner magnet opposed to the target being invertible; and a yoke surrounding the inner magnet with a spacing from the inner magnet.

According to still another aspect of the invention, there is provided a magnetron sputtering magnet assembly movable in a direction generally parallel to a sputtered surface of a target while facing the target, the magnetron sputtering magnet assembly including: a yoke extending in a direction generally perpendicular to the direction of the movement; and an outer magnet surrounding the yoke with a spacing from the yoke, the N pole or S pole of the outer magnet being opposed to the target, and the magnetic pole of the outer magnet opposed to the target being invertible.

According to still another aspect of the invention, there is provided a magnetron sputtering device including: a support unit on which an object under film formation is supported; a target opposed to the support unit; and the magnet assembly as mentioned above.

According to still another aspect of the invention, there is provided a magnetron sputtering method including: placing an object under film formation so as to face a target; and performing sputtering film formation on the object under film formation while linearly moving a magnet assembly on a side of the target opposite to the surface opposed to the support unit with the magnet assembly opposed to the target, the magnetic pole opposed to the target being switched when the magnet assembly is located at an end of the target.

### BRIEF DESCRIPTION OF DRAWINGS

FIGS. 1A and 1B are schematic view for illustrating the planar structure of a magnet assembly and a method for scanning a target according to a first embodiment of the invention.

FIG. 2 is a schematic view showing the cross-sectional structure of the magnet assembly.

FIG. 3 is a schematic view showing the main part of the magnetron sputtering device according to this embodiment of the invention.

FIGS. 4A and 4B are schematic view for describing another example of a method for scanning a target.

FIG. 5 is a schematic view showing the cross-sectional structure of a magnet assembly according to a second embodiment of the invention.

FIG. 6 is a schematic view showing the cross-sectional structure of a magnet assembly according to a third embodiment of the invention.

FIG. 7 is a schematic view showing the cross-sectional structure of a magnet assembly according to a fourth embodiment of the invention.

FIG. 8 is a schematic view showing the cross-sectional structure of a magnet assembly according to a fifth embodiment of the invention.

FIG. 9 is a view describing a moving trajectory of a sputtering magnet in a conventional example.

### DESCRIPTION OF REFERENCE NUMERALS

1 magnet assembly
3 inner magnet
5 outer magnet
7 nonmagnetic member
12 shaft member
13 rotary bearing
14 ball screw
15 motor
22 inner magnetic member
24 outer magnetic member
26 coil
28 yoke
32 inner magnet
34 outer magnet
36 nonmagnetic member
37, 38 yoke
42 inner magnet
44 yoke
46 nonmagnetic member
50 target
51 backing plate
53 support unit
54 object under film formation
62 inner magnet
63 yoke
100 orbit of electrons
102 magnetic field
150 target

### Best Mode for Carrying Out the Invention

Embodiments of the invention will now be described with reference to the drawings.

### First Embodiment

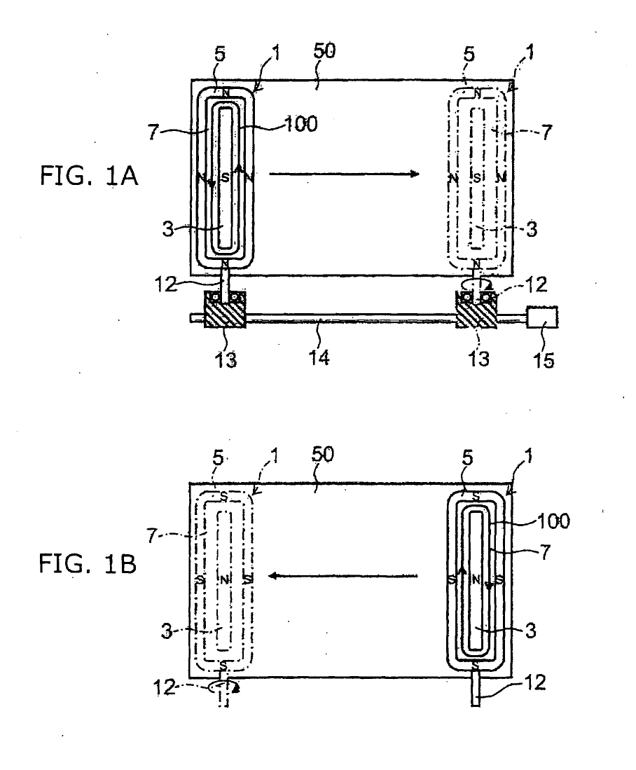

FIG. 1 is a schematic view for illustrating the planar structure of a magnet assembly 1 and a method for scanning a target 50 according to a first embodiment of the invention.

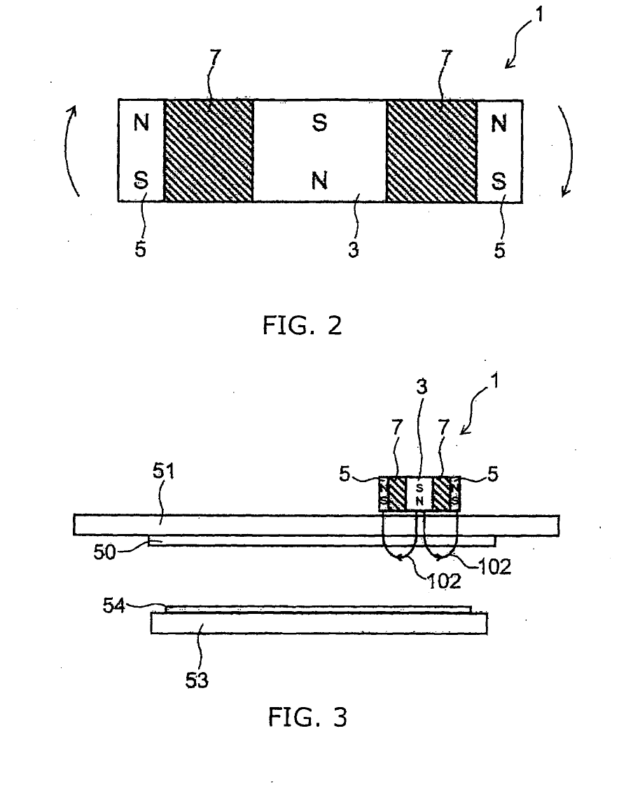

FIG. 2 is a schematic view showing the cross-sectional structure of the magnet assembly 1.

FIG. 3 is a schematic view showing the main part of a magnetron sputtering device provided with the magnet assembly 1.

The magnet assembly 1 according to this embodiment includes an inner magnet 3 and an outer magnet 5, which are both permanent magnets. The inner magnet 3 and the outer magnet 5 are held by a nonmagnetic member 7. The inner magnet 3, the outer magnet 5, and the nonmagnetic member 7 are integrated together and reciprocated in a direction generally parallel to the sputtered surface of the target 50 (illustratively, the longitudinal direction of the target) while facing the target 50.

As shown in FIG. 3, the target 50 is held by a backing plate 61 and opposed to the subject surface of an object under film formation 54 supported by a support unit 53. The object under film formation 54 is illustratively a semiconductor wafer or a glass substrate. In this example, the object under film formation 54 is illustratively a relatively large, rectangular glass substrate used for a liquid crystal panel or a solar cell panel, and the target 50 is shaped like a rectangular plate having a larger planar size than the glass substrate.

As shown in FIG. 3, the magnet assembly 1 is disposed on the backside (the opposite side of the target holding surface) of the backing plate 51 and faces the target 50 across the backing plate 51. It is noted that the backing plate 51 is not shown in FIG. 1. The magnet assembly 1 can be moved by the moving means, described later, along the longitudinal direction of the target 50 from end to end in the longitudinal direction of the target 50.

The inner magnet 3 in the magnet assembly 1 is shaped like a rectangular parallelepiped. Its longitudinal direction extends in a direction (the width direction of the target 50) generally perpendicular to the moving direction of the magnet assembly 1, and the N pole or the S pole is opposed to the target 50.

The outer magnet 5 is spaced from the inner magnet 3 and surrounds the surface of the inner magnet 3 except its magnetic pole surface in an elliptic or rectangular ring configuration. The magnetization direction of the outer magnet 5 is opposite to that of the inner magnet 3, and the magnetic pole opposed to the target 50 is opposite to that of the inner magnet 3.

A nonmagnetic member 7 is interposed between the inner magnet 3 and the outer magnet 5. The inner magnet 3 and the outer magnet 5 are held by the nonmagnetic member 7.

The longitudinal dimension of the magnet assembly 1 is slightly smaller than the width dimension of the target 50. The width dimension of the magnet assembly 1 is not more than half the longitudinal dimension of the target 50. The magnet assembly 1 includes no yoke on either of the side facing the target 50 and the opposite side.

The magnetic field 102 generated by the magnet assembly 1 produces a tunnel of the magnetic field 102 on the surface of the target 50 in a racetrack configuration, and electrons in the discharge space revolve in the magnetic field tunnel as indicated by the orbit 100. Thus, even in a high vacuum, ionization of gas molecules near the target surface is facilitated so that the state of a high-density plasma near the target surface can be maintained.

The magnet assembly 1 is invertibly provided so that the magnetic pole facing the target 50 can be inverted in each of the inner magnet 3 and the outer magnet 5. For example, as shown in FIG. 1, at one longitudinal end of the magnet assembly 1, a shaft member 12 extending in the longitudinal direction is provided. The shaft member 12 is rotatably held on a rotary bearing 13. Hence, the magnet assembly 1 is rotatable about the central axis of the shaft member 12.

The rotary bearing 13 is screwed on a ball screw 14 extending in the longitudinal direction of the target 50. When the ball screw 14 is rotated by a motor 15, the rotary bearing 13 is moved in the longitudinal direction of the target 50. With the movement of the rotary bearing 13, the magnet assembly 1 coupled to the rotary bearing 13 via the shaft member 12 is also moved in the longitudinal direction of the target 50.

During sputtering film formation, the target 50 is traversed (scanned) by the magnet assembly 1 from end to end in the longitudinal direction of the target 50. Thus, the nonuniformity of the in-plane film thickness distribution on the object under film formation 54 can be reduced to improve the uniformity of film thickness, and the bias of the erosion position on the target 50 can also be reduced to improve target utilization efficiency.

During one round of sputtering film formation, the magnet assembly 1 is moved linearly in the longitudinal direction of the target 50. Furthermore, in this embodiment, when the magnet assembly 1 is located at the movement start position (scan start point), the movement end position (scan end point), and the turnaround position of reciprocation, it is inverted upside down.

As shown in FIG. PA, for example, first, with the N pole of the inner magnet 3 opposed to the target 50 and the S pole of the outer magnet 5 opposed to the target 50, the magnet assembly 1 is moved from the position shown by the solid line to the position shown by the dot-dashed line.

Then, after the magnet assembly 1 is moved to the end position shown by the dot-dashed line in FIG. MA, the magnet assembly 1 is inverted upside down by rotation about the shaft member 12 so that as shown by the solid line in FIG. 1B, the S pole of the inner magnet 3 faces the target 50 and that the N pole of the outer magnet 5 faces the target 50. Then, in that state, in FIG. 1B, the magnet assembly 1 is moved from the position shown by the solid line to the position shown by the dot-dashed line, in the direction opposite to the previous direction.

Then, after the magnet assembly 1 is moved to the end position shown by the dot-dashed line in FIG. 1B, the magnet assembly 1 is inverted upside down by rotation about the shaft member 12 so that as shown by the solid line in FIG. PA, the N pole of the inner magnet 3 faces the target 50 and that the S pole of the outer magnet 5 faces the target 50.

In the case where the magnet assembly 1 reciprocates two or more times during one round of sputtering film formation, the above operation is repeated. It is noted that when the magnet assembly 1 is inverted at the target end position, electric discharge between the target and the object under film formation (between the cathode and the anode) is paused.

By inverting the magnet assembly 1 at the end position of the target 50, the direction of revolution in the racetrack-shaped orbit 100 of electrons near the target surface can be reversed. Thus, the nonuniformity of electron density in the target width direction at the utmost end of the target 50 (which is not traversed by the magnet assembly 1, but faces only half of the width) can be canceled out (in particular, the portion with low electron density near the corner portion extending from the long side portion to the short side portion in the magnet assembly 1 can be eliminated) to make the plasma density uniform in the target width direction. Thus, the sputtering rate can be made uniform in the width direction at the target end portion, and the nonuniformity of film formation distribution on the object under film formation can be reduced. Furthermore, the nonuniformity of target erosion can also be decreased to improve target utilization efficiency.

With regard to the timing for inverting the magnet assembly 1, the inversion may be performed for each reciprocating scan at the turnaround and at the time of return to the start position. In the case of performing a plurality of reciprocating scans, it may be inverted at the target end position once in several reciprocations. At the target end position, the number of times that electrons revolve in one direction is preferably equal to the number of times that electrons revolve in the opposite direction.

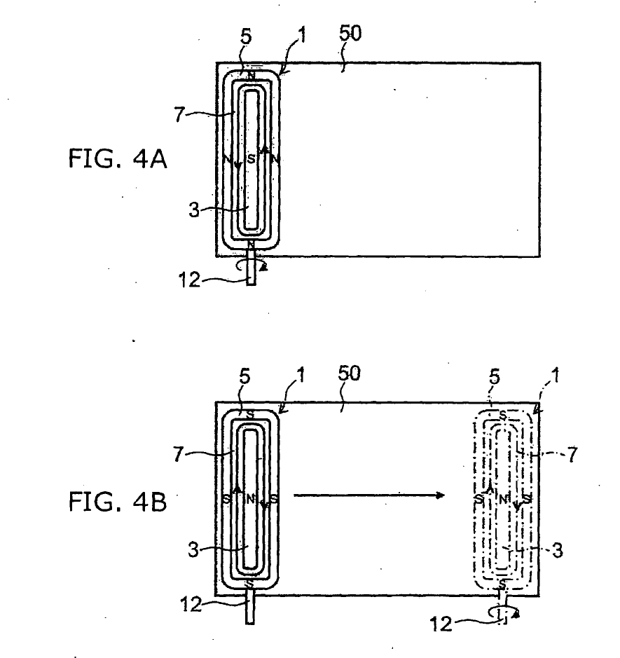

The magnet assembly 1 is not limited to the reciprocating scan, but can be moved in a one-way scan. For example, as shown in FIG. 4A, at one end (scan start position) of the target 50, first, sputtering film formation is performed with the N pole of the inner magnet 3 opposed to the target 50 and the S pole of the outer magnet 5 opposed to the target 50. Then, the magnet assembly 1 is inverted so that as shown by the solid line in FIG. 4B, the S pole of the inner magnet 3 faces the target 50 and that the N pole of the outer magnet 5 faces the target 50. Then, after sputtering film formation is performed in that state, the magnet assembly 1 is moved from the end position (scan start position) shown by the solid line to the other end position (scan end position) shown by the dot-dashed line in FIG. 4B.

Then, after the magnet assembly 1 is moved to the end position shown by the dot-dashed line in FIG. 4B, the magnet assembly 1 is inverted, and sputtering film formation is performed with the S pole of the inner magnet 3 opposed to the target 50 and the N pole of the outer magnet 5 opposed to the target 50. After that, the magnet assembly 1 is inverted so that the N pole of the inner magnet 3 faces the target 50 and that the S pole of the outer magnet 5 faces the target 50, and sputtering film formation is performed in that state.

Also in the one-way scan shown in FIG. 4, by inverting the magnet assembly 1 at the end position of the target 50, the direction of the racetrack-shaped revolution of electrons near the target surface can be reversed. Thus, the nonuniformity of electron density in the target width direction at the utmost end of the target 50 (which is not traversed by the magnet assembly 1, but faces only half of the width) can be canceled out.

In the following, other embodiments of the invention are described. It is noted that the same components as those described above are labeled with like reference numerals, and the detailed description thereof is omitted.

### Second Embodiment

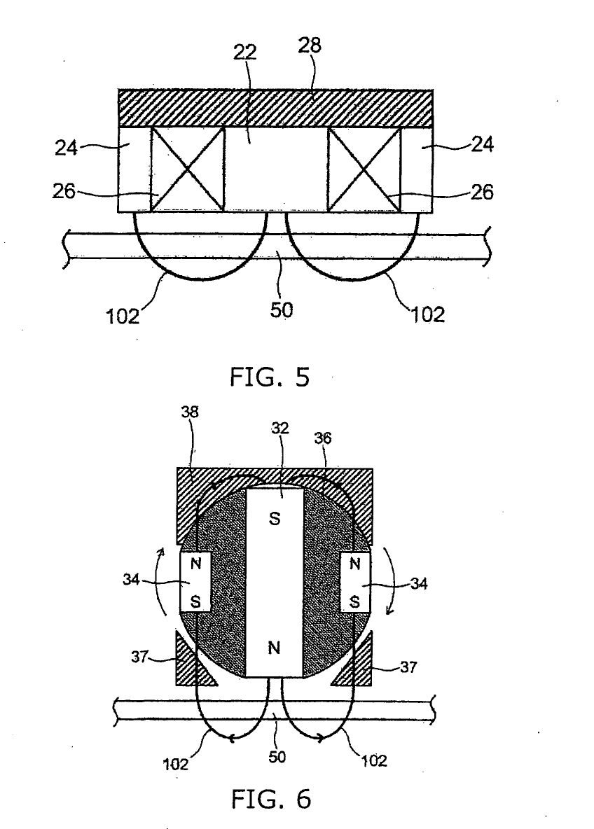

FIG. 5 is a schematic view showing the cross-sectional structure of a magnet assembly according to a second embodiment of the invention.

The magnet assembly according to this embodiment is an electromagnet. More specifically, the magnet assembly according to this embodiment includes an inner magnetic member 22 extending in the width direction of the target 50, a coil 26 wound around the inner magnetic member 22, an outer magnetic member 24 surrounding the coil 26, and a yoke 28 provided on the surface of the inner magnetic member 22, the outer magnetic member 24, and the coil 26 opposite to the surface opposed to the target 50.

The magnet assembly according to this embodiment is linearly moved in the longitudinal direction of the target 50 with the side opposite to the surface provided with the yoke 28 being opposed to the target 50. At the target end position, by varying the direction of the current passed through the coil 26, the magnetic pole occurring at the end of the inner magnetic member 22 facing the target 50 can be switched to reverse the direction of the racetrack-shaped revolution of electrons. Thus, the nonuniformity of electron density in the width direction at the utmost end of the target 50 can be canceled out to make the plasma density uniform in the target width direction.

According to this embodiment, the magnetic pole is switched simply by switching the direction of the current passed through the coil 26. Hence, there is no need to provide a mechanism for inverting the magnet assembly, and the configuration can be simplified.

### Third Embodiment

FIG. 6 is a schematic view showing the cross-sectional structure of a magnet assembly according to a third embodiment of the invention.

In the magnet assembly according to this embodiment, an inner magnet 32, an outer magnet 34, and a nonmagnetic member 36 provided therebetween are shaped like a cylinder having a central axis generally parallel to the width direction of the target 50. The inner magnet 32 is incorporated in the diameter direction of the nonmagnetic member 36 so as to divide the nonmagnetic member 36 in the longitudinal direction of the target 50, and the inner magnet 32 is magnetized in that diameter direction. The pole-forming end surface of the inner magnet 32 is exposed from the nonmagnetic member 36.

A racetrack-shaped groove is formed on the side surface of the nonmagnetic member 36 spaced approximately 900 from the pole-forming end surface of the inner magnet 32, and the outer magnet 34 is fitted into the groove. The inner magnet 32 and the outer magnet 34 have opposite magnetization directions. The dimension of the outer magnet 34 in the magnetization direction is smaller than the dimension of the inner magnet 32 in the magnetization direction. The outer magnet 34 is placed centrally in the magnetization direction of the inner magnet 32.

The inner magnet 32, the outer magnet 34, and the nonmagnetic member 36 are integrally rotatable about the center of the inner magnet 32 in the magnetization direction. With respect to the cylindrical rotating body composed of the inner magnet 32, the outer magnet 34, and the nonmagnetic member 36, on the side opposite to the portion facing the target 50 is provided a yoke 38. The inner portion of the yoke 38 facing the rotating body has a concave surface conforming to the outer peripheral surface of the rotating body.

When the inner magnet 32 is in a position with the N pole or the S pole opposed to the target 50, on the outside of the nonmagnetic member 36 located on both sides of that magnetic pole is disposed a yoke 37. Thus, as shown in FIG. 6, a magnetic circuit producing a closed-loop magnetic field 102 can be configured near the surface of the target 50.

The cylindrical rotating body composed of the inner magnet 32, the outer magnet 34, and the nonmagnetic member 3, and the yokes 37, 38 are integrated together and linearly moved in the longitudinal direction of the target 50. The rotating body is rotatable about the center of the inner magnet 32 in the magnetization direction (the yokes 37, 38 are not rotated). By inverting the rotating body at the end position of the target 50, the magnetic pole facing the target 50 can be switched, and the direction of the racetrack-shaped revolution of electrons near the target surface can be reversed. Thus, the nonuniformity of electron density in the width direction at the utmost end of the target 50 can be canceled out to make the plasma density uniform in the target width direction.

In the above first embodiment, in the case of a small spacing between the magnet assembly and the target (exactly, the backing plate), when the magnet assembly is inverted, the magnet assembly needs to be temporarily distanced from the target, and a mechanism therefore is separately needed. In contrast, in this embodiment shown in FIG. 6, the rotating body having a generally circular cross section is rotated. Hence, the rotating body can be rotated without varying the spacing between the rotating body and the target, which is set to a prescribed spacing. Thus, the magnetic pole can be switched easily and rapidly.

### Fourth Embodiment

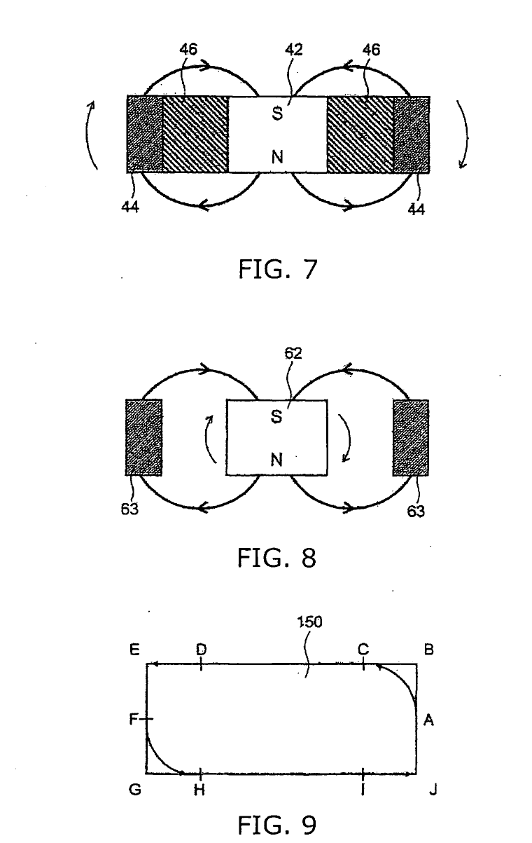

FIG. 7 is a schematic view showing the cross-sectional structure of a magnet assembly according to a fourth embodiment of the invention.

The magnet assembly according to this embodiment includes an inner magnet 42 extending in the width direction of the target 50 with the N pole or the S pole opposed to the target, a yoke 44 surrounding the inner magnet 42 with a spacing from the inner magnet 42, and a nonmagnetic member 46 provided between the inner magnet 42 and the yoke 44 and holding the inner magnet 42 and the yoke 44.

With the N pole or the S pole of the inner magnet 42 opposed to the target, the inner magnet 42, the nonmagnetic member 46, and the yoke 44 are integrated together and linearly moved in the longitudinal direction of the target 50. By inverting the magnet assembly at the target end position, the magnetic pole of the inner magnet 42 facing the target can be switched, and the direction of the racetrack-shaped revolution of electrons near the target surface can be reversed. Thus, the nonuniformity of electron density in the width direction at the utmost end of the target can be canceled out to make the plasma density uniform in the target width direction.

As an alternative configuration, by reversing the layout of the inner and outer member in FIG. 7, the yoke can be provided inside, the outer magnet can be provided around the yoke with a spacing from the yoke, and the nonmagnetic member holding them can be provided between the yoke and the outer magnet, so that the magnetic pole of the outer magnet facing the target can be inverted.

### Fifth Embodiment

FIG. 8 is a schematic view showing the cross-sectional structure of a magnet assembly according to a fifth embodiment of the invention.

The magnet assembly according to this embodiment includes an inner magnet 62 extending in the width direction of the target 50 with the N pole or the S pole opposed to the target, and a yoke 63 surrounding the inner magnet 62 with a spacing from the inner magnet 62. The inner magnet 62 is invertibly provided so that the magnetic pole facing the target can be inverted.

With the N pole or the S pole of the inner magnet 62 opposed to the target, the inner magnet 62 and the yoke 63 are integrated together and linearly moved in the longitudinal direction of the target 50. By inverting only the inner magnet 62 at the target end position, the magnetic pole of the inner magnet 62 facing the target can be switched, and the direction of the racetrack-shaped revolution of electrons near the target surface can be reversed. Thus, the nonuniformity of electron density in the width direction at the utmost end of the target can be canceled out to make the plasma density uniform in the target width direction.

As an alternative configuration, by reversing the layout of the inner and outer member in FIG. 8, the yoke can be provided inside, and the outer magnet can be provided around the yoke with a spacing from the yoke, so that the magnetic pole of the outer magnet facing the target can be inverted.

### INDUSTRIAL APPLICABILITY

According to the invention, the nonuniformity of electron density at the end of the target can be reduced, and the plasma density therein can be made uniform. Thus, the sputtering rate at the target end can be made uniform, and the nonuniformity of film formation distribution on the object under film formation can be reduced. Furthermore, the nonuniformity of target erosion can also be decreased to improve target utilization efficiency.

1. A magnetron sputtering magnet assembly movable in a direction generally parallel to a sputtered surface of a target while facing the target, the magnetron sputtering magnet assembly comprising:
an inner magnet extending in a direction generally perpendicular to the direction of the movement, the N pole or S pole of the inner magnet being opposed to the target;
an outer magnet surrounding the inner magnet with a spacing from the inner magnet, the magnetic pole of the outer magnet opposed to the target being opposite to that of the inner magnet; and
a nonmagnetic member provided between the inner magnet and the outer magnet and holding the inner magnet and the outer magnet,
the magnetic pole opposed to the target in each of the inner magnet and the outer magnet being invertible.

2. The magnetron sputtering magnet assembly according to claim 1, wherein the magnetron sputtering magnet assembly is shaped like a cylinder having a central axis generally parallel to the direction generally perpendicular to the direction of the movement.

3. A magnetron sputtering magnet assembly movable in a direction generally parallel to a sputtered surface of a target while facing the target, the magnetron sputtering magnet assembly comprising:
an inner magnetic member extending in a direction generally perpendicular to the direction of the movement;
a coil wound around the inner magnetic member;
an outer magnetic member surrounding the coil; and
a yoke provided on a surface of the inner magnetic member, the outer magnetic member, and the coil, the surface being opposite to a surface thereof opposed to the target,
the magnetic pole occurring at an end portion of the inner magnetic member opposed to the target being switched by varying the direction of a current passed through the coil.

4. A magnetron sputtering magnet assembly movable in a direction generally parallel to a sputtered surface of a target while facing the target, the magnetron sputtering magnet assembly comprising:
an inner magnet extending in a direction generally perpendicular to the direction of the movement, the N pole or S pole of the inner magnet being opposed to the target;
a yoke surrounding the inner magnet with a spacing from the inner magnet; and
a nonmagnetic member provided between the inner magnet and the yoke and holding the inner magnet and the yoke,
the magnetic pole of the inner magnet opposed to the target being invertible.

5. A magnetron sputtering magnet assembly movable in a direction generally parallel to a sputtered surface of a target while facing the target, the magnetron sputtering magnet assembly comprising:
a yoke extending in a direction generally perpendicular to the direction of the movement;
an outer magnet surrounding the yoke with a spacing from the yoke, the N pole or S pole of the outer magnet being opposed to the target; and
a nonmagnetic member provided between the yoke and the outer magnet and holding the yoke and the outer magnet,
the magnetic pole of the outer magnet opposed to the target being invertible.

6. A magnetron sputtering magnet assembly movable in a direction generally parallel to a sputtered surface of a target while facing the target, the magnetron sputtering magnet assembly comprising:
an inner magnet extending in a direction generally perpendicular to the direction of the movement, the N pole or S pole of the inner magnet being opposed to the target, and the magnetic pole of the inner magnet opposed to the target being invertible; and
a yoke surrounding the inner magnet with a spacing from the inner magnet.

7. A magnetron sputtering magnet assembly movable in a direction generally parallel to a sputtered surface of a target while facing the target, the magnetron sputtering magnet assembly comprising:
a yoke extending in a direction generally perpendicular to the direction of the movement; and
an outer magnet surrounding the yoke with a spacing from the yoke, the N pole or S pole of the outer magnet being opposed to the target, and the magnetic pole of the outer magnet opposed to the target being invertible.

8. A magnetron sputtering device comprising:
a support unit on which an object under film formation is supported;
a target opposed to the support unit; and
the magnet assembly according to any one of claims 1 to

7.

9. A magnetron sputtering method comprising:
placing an object under film formation so as to face a target; and
performing sputtering film formation on the object under film formation while linearly moving a magnet assembly on a side of the target opposite to the surface opposed to the support unit with the magnet assembly opposed to the target,
the magnetic pole opposed to the target being switched when the magnet assembly is located at an end of the target.

10. The magnetron sputtering method according to claim 9, wherein the magnetic pole opposed to the target is switched by inverting the magnet assembly upside down.

11. The magnetron sputtering method according to claim 9, wherein the magnet assembly is an electromagnet, and the magnetic pole opposed to the target is switched by switching a current passed through a coil of the electromagnet.
